(19) United States
(12) Patent Application Publication
(10) Pub. No.: US 2005/0048795 A1
(43) Pub. Date: Mar. 3, 2005

(54) Method for ultra low-K dielectric deposition

(76) Inventors: Chung-Chi Ko, Nantou (TW); Yung-Cheng Lu, Taipei (TW); Tien-I Bao, Hsin-Chu (TW); Hui-Lin Chang, Hsin-Chu (TW); Syun-Ming Jang, Hsin-Chu (TW)

Correspondence Address: SLATER & MATSIL, L.L.P., 17950 PRESTON RD, SUITE 1000, DALLAS, TX, 75252-5793, US

(21) Appl. No.: 10/649,566

(22) Filed: Aug. 27, 2003

(51) Int. Cl. H01L 21/31; H01L 21/469

(52) U.S. Cl. 438/778; 438/781

(57) ABSTRACT

The present invention provides a method of forming a semiconductor structure having an ultra low-K dielectric material that adheres well to the substrate. The method includes depositing a low-K material on the top surface of a substrate at a low temperature of no more than 250° by a CVD or spin-on process. The dielectric material is then cured by placing the substrate with the dielectric film in an environment where the temperature is regulated at about 400° or less as the dielectric film is being subjected to a plasma treatment or an E-beam treatment or UV treatment. The environment may further include one or more gases or a mixture of gases selected from the group consisting of H₂, N₂, NH₃, CO₂, all hydride gases and a mixture of these gases.

### TECHNICAL FIELD

The present invention relates generally to the deposition of dielectric materials used with a Damascene process for depositing copper interconnect lines, and more particularly to a method of depositing ultra low-K materials between the metal conductors deposited by the Damascene process.

### BACKGROUND

As is well known by those skilled in the art, a continuing goal in manufacturing and production of semiconductors is a reduction in size of components and circuits with the concurrent result of an increase in the number of circuits and/or circuit elements such as transistors, capacitors, etc., on a single semiconductor device. This relentless and successful reduction in size of the circuit elements has also required reduction in the size of the conductive lines connecting devices and circuits. However, as the conducting lines are designed to be smaller and smaller, the resistance of the interconnects increases. Further, as the number of dielectric layers increases, the capacitive coupling between lines on the same level and adjacent level increases.

In the past, aluminum was used as the metal interconnect lines and silicon oxide as the dielectric. However, to reduce line resistance and the capacitive coupling, newer manufacturing techniques now favor copper as the metal for interconnect lines and various low-K materials (organic and inorganic) are favored as the dielectric material. Not surprisingly, these material changes have required changes in the processing methods. For example, because of the difficulty of etching copper without also causing unacceptable damage to the dielectric material, the technique of forming the metal interconnect lines has experienced significant changes. Namely, whereas aluminum interconnects could be formed by depositing a layer of aluminum and then using photoresist, lithography, and etching to leave a desired pattern of aluminum lines, the formation of copper interconnect lines are typically formed by a process now commonly referred to as a Damascene process. The Damascene process is almost the reverse of etching, and simply stated a trench, canal or via is cut, etched or otherwise formed in the underlying dielectric and is then filled with metal (e.g., copper).

Various materials appear to be suitable for use with the Damascene deposited interconnect lines as an ultra low-K dielectric material. Unfortunately, problems arise in the depositing of this low-K dielectric material. For example, to achieve properly cured and stable materials along with satisfactory adhesion between the material and the substrate without also requiring an unacceptable amount of time to complete the process, the dielectric material is typically deposited by LPCVD (low pressure chemical vapor deposition) at high temperatures, PECVD (plasma enhanced chemical vapor deposition) at low temperatures, or even spin-on process followed by a high temperature curing step. However, as is known, ultra low-K materials are typically very porous materials and when the deposition temperature and/or curing temperature increases, the sintering or annealing effects of the high temperatures results in a density increase of the material. That is, when the porosity decreases, the dielectric constant K of the material will increase. Further, such high temperatures can also cause diffusion between the copper interconnect lines and the dielectric material. Therefore, a method of depositing and curing a dielectric material without unduly increasing the dielectric constant of the material or copper diffusion would be advantageous.

### SUMMARY OF THE INVENTION

These and other problems are generally solved or circumvented, and technical advantages are achieved by the present invention which describes a method of forming a semiconductor structure having an ultra low-K dielectric material on a substrate. The method comprises the steps of providing an environment which can maintain or regulate the temperature to a desired level. A substrate with a top surface such as, for example only, a silicon wafer, is placed in the environment and the temperature of the environment is maintained at a temperature of less than about 250° C. A material having a dielectric constant of 2.5 or less is then deposited over the top surface of the substrate by a CVD process or a spin-on process. The environment surrounding the substrate with the deposited layer is then maintained at a temperature of about 400° or less as the deposited layer is cured. The curing process is accomplished by a plasma treatment or an E-beam treatment and may be carried out in a gaseous environment selected from the gases H₂, N₂, NH₃, CO₂, all of the hydride gases, or a mixture of any of these gases. Once the low-K dielectric film is cured, it will now be securely adhered to the substrate and will also have improved structural strength.

### DESCRIPTION OF THE DRAWINGS

For a more complete understanding of the present invention, and the advantages reference is now made to the following descriptions taken in conjunction with the nying drawing, in which:

FIGS. 1A, 1B, 1C, 1D and 1E illustrate the depositing and curing process of the invention; and

FIG. 2 is a flow diagram of a process of the present invention.

### DETAILED DESCRIPTION OF ILLUSTRATIVE EMBODIMENTS

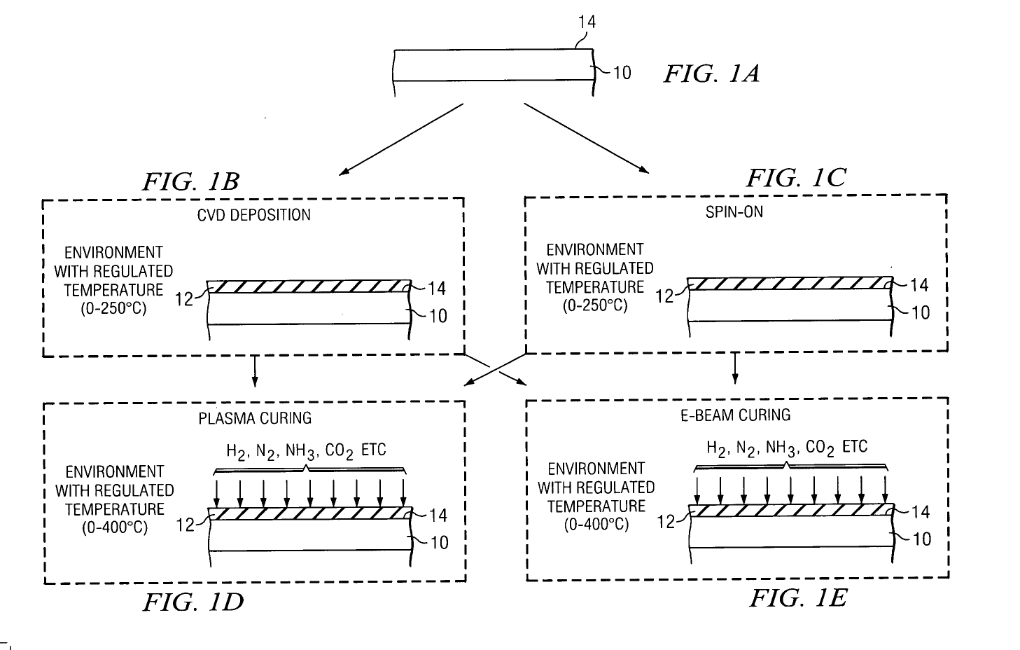

Referring now to FIG. 1A, there is shown a typical substrate 10 used in the manufacture of semiconductor devices. According to the present invention, the substrate is placed in a controlled environment where the temperature can be maintained at between about 0° C. and about 250° C. An ultra low-K dielectric material 12 is then deposited on the top surface 14 of the substrate by a CVD (chemical vapor deposition) process or a spin-on process at these low temperatures and as shown in FIGS. 1B and 1C, respectively. The term “ultra low-K” is used herein to mean a dielectric constant of between 1.9 and 2.5. Suitable examples of ultra low-K materials may include the SiLK™ manufactured by the Dow Chemical Company of Midland, Michigan, or an “organosilcate” material such as ORION™ manufactured by the Trikon company of Newport in the United Kingdom, porous MSQ films and various florocarbonated silicon films. For a material such as ORION™ a precursor such as methysilane (SiH₃CH₃) and hydrogen peroxide (H₂O₂). As an example, a material such as Tri-methyl silane(SiH(CH3)3) from Applied Materials of Santa Clara, Calif., can also be used.

As will be appreciated by those skilled in the art, and although excellent quality films may be deposited by such a low temperature CVD process as opposed to a PECVD (plasma enhanced) process, the film will not necessarily adhere well to the substrate unless properly cured. However, as will also be appreciated, since materials having ultra low-K dielectric constants usually achieve such a low dielectric constant by being very porous, curing by the normal process of using high temperatures above 400° C., would result in the density being increased. Of course, increasing the density will result in significantly lower porosity which in turn would very likely raise the dielectric constant well above the desired 2.5 level. It is therefore desirable to have a low-K dielectric material that exhibits an improvement in hardness and modules. As will be discussed below, using a plasma treatment and/or e-beam treatment could improve hardness and modules. Alternatively, or in addition, a UV (ultraviolet) treatment can be used.

Therefore, referring now to FIG. 1D, there is shown the combination substrate 10 and deposited ultra low-K dielectric film 12 structure of either of the CVD process of FIG. 1B or the spin-on process of FIG. 1C being subjected to a plasma treatment at a temperature of no more than 400° C. and which may include a gas environment of H₂, N₂, NH₃, CO₂, and all hydride gases or a mixture of these gases. The plasma treatment will cure the ultra low-K dielectric film such that the film will adhere to the top surface 14 of substrate 10 while maintaining a dielectric constant of 2.5 or less. In the preferred embodiment, the plasma treatment will be performed with a pressure of about 2-10 torr, a power of about 100-1000 W and a gas environment of about H₂ or NH₃ or N₂ or CO₂.

Alternately, or in addition, the deposited ultra low-K film can be subjected to an EB (electron beam) treatment such as shown in FIG. 1E. Again, the temperature is maintained at a temperature of less than about 400° C. as the substrate or wafer is subjected to an electron dose of about 30 to about 500/cm² while using an electron acceleration voltage of about 25 keV. This process also results in curing the film to increase adhesion without raising the dielectric constant above 2.5.

Alternatively, or in addition, the deposited ultra low-K film can be subjected to a UV (ultraviolet radiation) treatment (not shown in FIGS. 1A through 1E). Once again, the temperature is maintained at a temperature of less than about 400° C., as the substrate or wafer is subjected to the UV radiation.

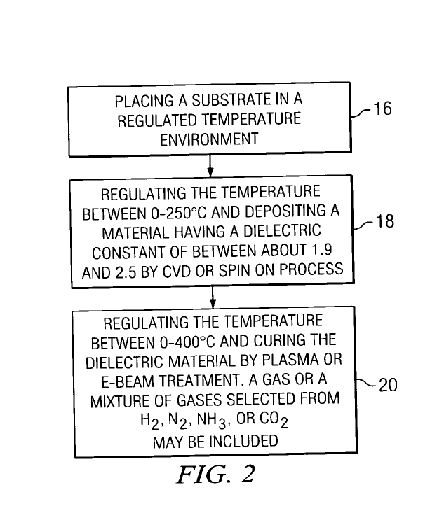

FIG. 2 illustrates the process steps discussed with respect to FIGS. 1A-1E. As shown in step 16, the substrate 10 having the top surface 14 is placed in an environment where the temperature can be regulated or controlled. Then, as shown in step 18, the temperature in the controlled environment is maintained at a level of between about 0° C. and 250° C. as a layer 12 of material having a dielectric constant of less than 2.5 and preferably between about 1.9 and 2.5 is deposited on the top surface 14 of substrate 10. The layer 12 may be deposited by a low temperature CVD process other than PECV as a low temperature spin-on process. The layer 12 of ultra low-K dielectric material is than cured as shown in step 20 by a plasma UV or electron beam (E-beam) process while maintaining the environment temperature at no more than 400° C.

Although the present invention and its advantages have been described in detail, it should be understood that various changes, substitutions and alterations can be made herein without departing from the spirit and scope of the invention as defined by the appended claims. For example, it will be readily understood by those skilled in the art that materials and pressures may be varied while remaining within the scope of the present invention.

Moreover, the scope of the present application is not intended to be limited to the particular embodiments of the process, methods and steps described in the specification. As one of ordinary skill in the art will readily appreciate from the disclosure of the present invention, processes, methods, or steps, presently existing or later to be developed, that perform substantially the same function or achieve substantially the same result as the corresponding embodiments described herein may be utilized according to the present invention. Accordingly, the appended claims are intended to include within their scope such processes, methods, or steps.

1. A method of forming a semiconductor structure comprising a low-K dielectric material on a substrate comprising the steps of:
providing an environment having a regulated temperature;
placing a substrate having a top surface in said environment;
regulating said temperature of said environment to between about 0° C. and 250° C.;
depositing a layer of material on said top surface of said substrate wherein said layer has a dielectric constant of no more than 2.5;
regulating the temperature of said environment between 0° C. and 400° C.; and
curing said deposited layer of material.

2. The method of claim 1 wherein said step of depositing is a process selected from the group consisting of a CVD process and a spin-on process.

3. The method of claim 2 wherein said step of depositing is a CVD process.

4. The method of claim 2 wherein said step of depositing is a spin-on process.

5. The method of claim 1 wherein said deposited layer has a dielectric constant of between about 1.9 and 2.5.

6. The method of claim 1 wherein said step of curing is a process selected from the group consisting of a plasma treatment, an E-beam treatment and a UV treatment.

7. The method of claim 6 wherein said step of curing is a plasma treatment.

8. The method of claim 6 wherein said step of curing is a E-beam treatment.

9. The method of claim 6 wherein said step of curing is a UV treatment.

10. The method of claim 2 wherein said step of curing is a process selected from the group consisting of a plasma treatment, an E-beam treatment and a UV treatment.

11. The method of claim 9 wherein said step of curing is a plasma treatment.

12. The method of claim 9 wherein said step of curing is a E-beam treatment.

13. The method of claim 9 wherein said step of curing is a UV treatment.

14. The method of claim 9 wherein said deposited layer has a dielectric constant of between about 1.9 and 2.5.

15. The method of claim 1 wherein said environment of said curing step further includes a gas selected from the group consisting of H₂, N₂, NH₃, CO₂, all hydride gases and a mixture of said gases.

16. The method of claim 2 wherein said environment of said curing step further includes a gas selected from the group consisting of H₂, N₂, NH₃, CO₂, all hydride gases and a mixture of said gases.

17. The method of claim 6 wherein said environment of said curing step further includes a gas selected from the group consisting of H₂, N₂, NH₃, CO₂, all hydride gases and a mixture of said gases.

18. The method of claim 9 wherein said environment of said curing step further includes a gas selected from the group consisting of H₂, N₂, NH₃, CO₂, all hydride gases and a mixture of said gases.

19. The method of claim 16 wherein said deposited layer has a dielectric constant of between bout 1.9 and 2.5.
